(19) United States
(12) Patent Application Publication
(10) Pub. No.: US 2025/0056943 A1
(43) Pub. Date: Feb. 13, 2025

(54) SEMICONDUCTOR DEVICE AND METHOD FOR MANUFACTURING SAME

(71) Applicant: Mitsubishi Electric Corporation, Tokyo (JP)

(72) Inventor: Chikara WATATANI, Tokyo (JP)

(73) Assignee: Mitsubishi Electric Corporation, Tokyo (JP)

(21) Appl. No.: 18/720,889

(22) PCT Filed: Mar. 1, 2022
(86) PCT No.: PCT/JP2022/008507

§ 371 Date: Jun. 17, 2024

(51) Int. Cl. H01L 33/62; H01L 23/00; H01L 33/06; H01L 33/44

(52) U.S. Cl. CPC H01L 33/62; H01L 24/03; H01L 24/05; H01L 33/06; H01L 33/44; H01L 2224/03464; H01L 2224/04042; H01L 2224/08054; H01L 2224/0807; H01L 2924/12041; H01L 2924/30105; H01L 2933/0066

(57) ABSTRACT

A semiconductor device according to the present disclosure includes: a semiconductor substrate; a first semiconductor layer formed on the semiconductor substrate; an insulating film formed on the first semiconductor layer; and a connecting electrode including a front surface electrode formed in contact with the insulating film and having a plurality of opening portions that expose the insulating film on the bottom surface, and a plating film formed in contact with the front surface electrode and covering the opening portions.

### TECHNICAL FIELD

The present disclosure relates to a semiconductor device and a method for manufacturing the same.

### BACKGROUND ART

In a semiconductor device driven by a high-frequency signal, it is an important factor for expanding a high-frequency bandwidth of a semiconductor circuit to minimize electrostatic capacitance generated in a connecting electrode for connecting a signal input line. This is because, in a case where the connecting electrode is formed on an insulating film, and conductive semiconductor layers are located under the insulating film, or a back surface electrode is formed on a back surface side of the semiconductor device, the electrostatic capacitance is generated between the connecting electrode and the semiconductor layers or the back surface electrode.

Even in the case where an insulating or semi-insulating semiconductor layer is formed between the connecting electrode and above-described conductive semiconductor layers or back surface electrode on the back surface side of the semiconductor device, the electrostatic capacitance is similarly generated. Consequently, from the viewpoint of reducing the electrostatic capacitance, it is preferable to form the connecting electrode on the insulating film with as small an area as possible.

In contrast, in the connection of the signal input line to the connecting electrode, especially in the case of wire bonding by a gold wire, the connecting electrode needs to be formed with an area larger than a radial area of the wire, and the large area of the connecting electrode facilitates position control during wiring connection.

### CITATION LIST

### Patent Document

Patent Document 1: Japanese Laid-Open Patent Publication No. 11-214579

### SUMMARY OF THE INVENTION

### Problem to be Solved by the Invention

The semiconductor device having a low capacitive electrode and a method for manufacturing the same disclosed in Patent Document 1 is one of the methods to reduce the electrostatic capacitance generated at the connecting electrode while maintaining the area of the wiring connection surface of the connecting electrode. In Patent Document 1, by forming voids in the semiconductor layer immediately below the connecting electrode, the average effect of the semiconductor portion and the void portion results in an apparent low dielectric constant structure. This is intended to reduce the electrostatic capacitance generated between the connecting electrode and the conductive semiconductor layer and/or between the connecting electrode and the back surface electrode.

However, in the semiconductor device and the method for manufacturing the same described in Patent Document 1, an additional process to form the voids in the semiconductor layer is required in the manufacturing process, resulting in an increase in manufacturing cost.

The present disclosure has been made to solve the above-described problems, and an object of the present disclosure is to provide a semiconductor device having excellent high-frequency characteristics without deteriorating the connectivity between a signal input line and a connecting electrode, and a method for manufacturing a semiconductor device which can reduce the manufacturing cost of the semiconductor device having excellent high-frequency characteristics.

### Means to Solve the Problem

A semiconductor device according to the present disclosure includes: a semiconductor substrate; a first semiconductor layer formed on the semiconductor substrate; an insulating film formed on the first semiconductor layer; and a connecting electrode including a front surface electrode formed in contact with the insulating film and having a plurality of opening portions that expose the insulating film on the bottom surface, and a plating film formed in contact with the front surface electrode and covering the opening portions.

A method for manufacturing a semiconductor device according to the present disclosure includes: a crystal growth step of growing a first semiconductor layer on a semiconductor substrate; an insulating film forming step of forming an insulating film on the first semiconductor layer; a front surface electrode forming step of forming a front surface electrode, on the insulating film, having a plurality of opening portions that expose the insulating film on the bottom surface; and a plating film forming step of depositing a plating film so as to cover the opening portions on the front surface electrode.

### Effect of the Invention

According to the semiconductor device of the present disclosure, the electrostatic capacitance generated in the wiring connection part can be reduced without deteriorating the connectivity between the signal input line and the connecting electrode in the wiring connection part, thus providing an effect of obtaining a semiconductor device having excellent high-frequency characteristics.

The method for manufacturing a semiconductor device according to the present disclosure has an effect of enabling a semiconductor device having excellent high-frequency characteristics to be manufactured without increasing a manufacturing cost for the semiconductor device.

### BRIEF DESCRIPTION OF THE DRAWINGS

FIG. 1 is a schematic view of a semiconductor device according to Embodiment 1;

FIG. 2 is a top view of a wiring connection part of the semiconductor device according to Embodiment 1;

FIG. 3 is a cross-sectional view of the wiring connection part of the semiconductor device according to Embodiment 1;

FIG. 4 is a cross-sectional view of the wiring connection part after an insulating film is formed in the method for manufacturing a semiconductor device according to Embodiment 1;

FIG. 5 is a cross-sectional view of the wiring connection part after a front surface electrode is formed in the method for manufacturing a semiconductor device according to Embodiment 1;

FIG. 6 is a cross-sectional view of the wiring connection part after forming opening portions in the front surface electrode in the method for manufacturing a semiconductor device according to Embodiment 1;

FIG. 7 is a cross-sectional view of the wiring connection part after a resist mask forming step for forming a plating pattern in the method for manufacturing a semiconductor device according to Embodiment 1;

FIG. 8 is a cross-sectional view of the wiring connection part after a plating film forming step in the method for manufacturing a semiconductor device according to Embodiment 1;

FIG. 9A is a cross-sectional view of the wiring connection part in the plating film forming step in the method for manufacturing a semiconductor device according to Embodiment 1;

FIG. 9B is a cross-sectional view of the wiring connection part in the plating film forming step in the method for manufacturing a semiconductor device according to Embodiment 1;

FIG. 9C is a cross-sectional view of the wiring connection part in the plating film forming step in the method for manufacturing a semiconductor device according to Embodiment 1;

FIG. 10 is a schematic view of a semiconductor device according to Embodiment 2;

FIG. 11 is a cross-sectional view of a wiring connection part of the semiconductor device according to Embodiment 2;

FIG. 12 is a cross-sectional view of the wiring connection part after formation of an insulating film in a method for manufacturing a semiconductor device according to Embodiment 2;

FIG. 13 is a cross-sectional view of the wiring connection part after formation of a front surface electrode in the method for manufacturing a semiconductor device according to Embodiment 2;

FIG. 14 is a cross-sectional view of the wiring connection part after forming opening portions in the front surface electrode in the method for manufacturing a semiconductor device according to Embodiment 2;

FIG. 15 is a cross-sectional view of the wiring connection part after a resist mask forming step for forming a plating pattern in the method for manufacturing a semiconductor device according to Embodiment 2;

FIG. 16 is a cross-sectional view of the wiring connection part after the plating film forming step in the method for manufacturing a semiconductor device according to Embodiment 2;

FIG. 17A is a cross-sectional view of the wiring connection part in the plating film forming step in the method for manufacturing a semiconductor device according to Embodiment 2;

FIG. 17B is a cross-sectional view of the wiring connection part in the plating film forming step in the method for manufacturing a semiconductor device according to Embodiment 2;

FIG. 17C is a cross-sectional view of the wiring connection part in the plating film forming step in the method for manufacturing a semiconductor device according to Embodiment 2;

FIG. 18 is a schematic view of a semiconductor device according to Embodiment 3;

FIG. 19 is a view of a wiring connection part of the semiconductor device according to Embodiment 3 as viewed from the top surface of the semiconductor device;

FIG. 20 is a cross-sectional view of the wiring connection part of the semiconductor device according to Embodiment 3;

FIG. 21 is a cross-sectional view of the wiring connection part after notch-shaped opening portions are formed in a front surface electrode in the method for manufacturing a semiconductor device according to Embodiment 3;

FIG. 22 is a cross-sectional view of the wiring connection part after a resist mask forming step for forming a plating pattern in the method for manufacturing a semiconductor device according to Embodiment 3;

FIG. 23 is a cross-sectional view of the wiring connection part after a plating film forming step in the method for manufacturing a semiconductor device according to Embodiment 3;

FIG. 24 is a schematic view of a semiconductor device according to Embodiment 4;

FIG. 25 is a view of a wiring connection part of the semiconductor device according to Embodiment 4, as viewed from the top surface of the semiconductor device;

FIG. 26 is a schematic view showing a state where an input signal line is connected to a connecting electrode of the semiconductor device according to Embodiment 4.

### DESCRIPTION OF EMBODIMENTS

### Embodiment 1

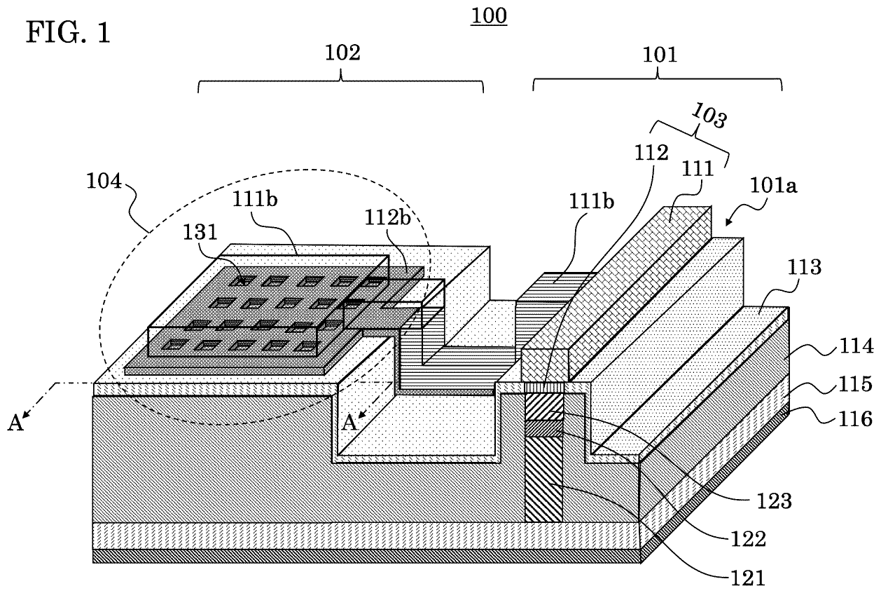

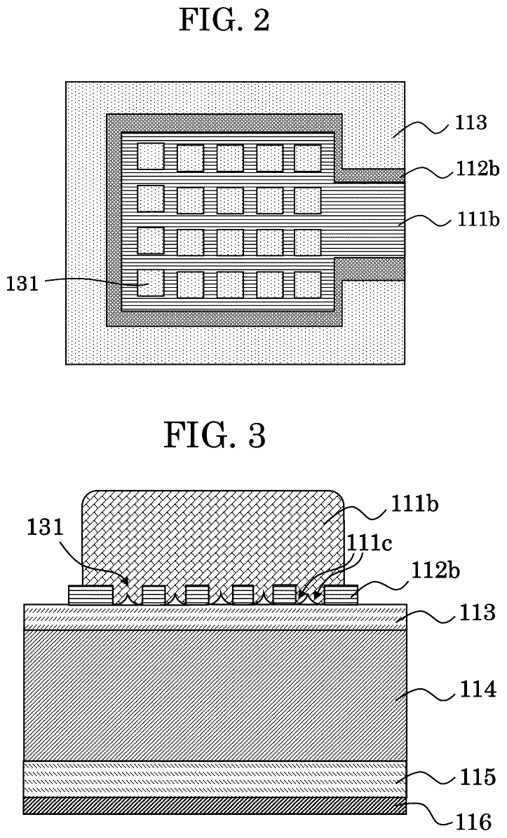

FIG. 1 is a schematic view of a semiconductor device 100 according to Embodiment 1. FIG. 2 is a top view of the wiring connection part of the semiconductor device 100 according to Embodiment 1. FIGS. 1 and 2 illustrate a semiconductor optical device as an example of the semiconductor device 100. But the present disclosure is not limited to the semiconductor optical device and is applicable to semiconductor devices that require high-frequency operation.

Hereinafter, the semiconductor optical device as an example of the semiconductor device 100 will be described. The semiconductor device 100 includes a light emitting part 101 composed of a ridge structure 101a and a wire connecting part 102 for connecting a signal input line for inputting a high-frequency signal to the light emitting part 101. A connecting electrode 104 is provided in the mesa-structured wiring connection 102 which is located on the lateral side of the light emitting part 101 composed of the ridge structure 101a.

A first semiconductor layer 114 is provided on a semiconductor substrate 115. In the light emitting part 101, the first semiconductor layer 114 functions as a buried layer for burying the ridge structure 101a described later. In the wiring connection part 102, the first semiconductor layer 114 functions to support the connecting electrode 104 through the insulating film 113. The first semiconductor layer 114 is preferably formed of a semi-insulating semiconductor layer in order to concentrate a current on a semiconductor quantum well layer 122 described later. But, the first semiconductor layer 114 is not limited to the semi-insulating semiconductor layer, and may be made of a semiconductor of a first-conductivity-type or a second-conductivity-type.

The light emitting part 101 includes: the ridge structure 101a formed on the semiconductor substrate 115; an insulating film 113 provided on both side surfaces of the ridge structure 101a; a ridge-side front surface electrode 112 provided in contact with the upper surface of the ridge structure 101a through an opening portion of the insulating film 113 formed on the upper surface of the ridge structure 101a; and a ridge-side plating film 111 provided on the ridge-side front surface electrode 112. The ridge-side front surface electrode 112 and the ridge-side plating film 111 are collectively referred to as a ridge-side electrode 103.

The ridge structure 101a is composed of a first-conductivity-type second semiconductor layer 121, the semiconductor quantum well layer 122, a second-conductivity-type third semiconductor layer 123, which are sequentially formed on the semiconductor substrate 115, and the first semiconductor layer 114 formed so as to cover the side surfaces of the respective layers. A back surface electrode 116 is provided on the back surface side of the semiconductor substrate 115, that is, on the side opposite to the front surface side on which the ridge structure 101a and the connecting electrode 104 are provided.

The wiring connection part 102 is composed of the first semiconductor layer 114 formed on the semiconductor substrate 115, the insulating film 113 provided on the first semiconductor layer 114, and the connecting electrode 104.

The connecting electrode 104 is composed of: a front surface electrode 112b formed in contact with the insulating film 113 and having a plurality of opening portions 131 exposing the insulating film 113 on the bottom surface thereof; and a plating film 111b formed in contact with the front surface electrode 112b, covering the opening portions 131, and having portions 111c formed so as to extend toward the bottom side of the opening portions 131. In FIGS. 1 and 2, the plating film 111b is shown in a transparent manner to show the internal structure of the connecting electrode 104. The structure of the connecting electrode 104 will be described in detail later.

The ridge-side electrode 103 provided in the light emitting part 101 and the connecting electrode 104 provided in the wiring connection part 102 are electrically connected to each other.

The ridge-side front surface electrode 112 provided on the front surface side of the semiconductor device 100 and the back surface electrode 116 provided on the back surface side of the semiconductor device 100 are electrically connected to each other through the first-conductivity-type second semiconductor layer 121, the semiconductor quantum well layer 122, and the second-conductivity-type third semiconductor layer 123. Input signals are applied to the ridge-side front surface electrode 112 by a predetermined voltage or current, then electrons and holes combine in the semiconductor quantum well layer 122, thus emitting light.

As shown in FIG. 2, which is a top view of the wiring connection part 102 of the semiconductor device 100, the front surface electrode 112b constituting the connecting electrode 104 has a shape in which a plurality of opening portions 131 are uniformly formed therein. In the example shown in FIG. 2, the connecting electrode 104 has a rectangular shape in a top view, and the plurality of opening portions 131 are arranged in a lattice pattern in the rectangular-shaped portion of the front surface electrode 112b. The insulating film 113 is exposed on the bottom surface of the opening portions 131.

Arranging the opening portions 131 as described above enables the distribution of adhesion force between the front surface electrode 112b and the insulating film 113 to be maintained uniformly at the connecting electrode 104. The plating film 111b is provided in contact with the front surface electrode 112b.

The plating film 111b covers the opening portions 131 in the front surface electrode 112b. Some parts of the plating film 111b form portions 111c that extend toward the bottom side of the opening portions 131. The shape of the portions 111c of the plating film 111b will be described later.

FIG. 3 is a cross-sectional view of the wiring connection part 102 taken along line A-A in FIG. 1. The wiring connection part 102 includes: the first semiconductor layer 114 formed on the semiconductor substrate 115; the insulating film 113 provided on the first semiconductor layer 114; and the connecting electrode 104 having the front surface electrode 112b formed on the insulating film 113, and the plating film 111b. The back surface electrode 116 is provided on the back surface side of the semiconductor substrate 115. The opening portions 131 as shown in FIG. 2 are provided in the lattice pattern in the front surface electrode 112b. In the cross-sectional view of the wiring connection part 102 shown in FIG. 3, the opening portions 131 are arranged in the lattice pattern at regular intervals. The insulating film 113 is exposed on the bottom surface of the opening portions 131.

The plating film 111b is provided so as to be in contact with the front surface electrode 112b, and thus covers the openings of the opening portions 131. In the area of the plating film 111b covering each opening portion 131, a part of the plating film 111b extends along the side surface of the opening portion 131 and into the inside thereof toward the bottom side. That is, the part of the plating film 111b forms the portion 111c which extends into the inside of each opening portion 131 toward the bottom side. Therefore, the contact area between the front surface electrode 112b and the plating film 111b is reduced by the area of the opening portions 131 due to providing the opening portions 131, while the part of the plating film 111b extends to inside along the side surface of the opening portion 131 to form the portion 111c, thus providing an effect of maintaining superior adhesion between the front surface electrode 112b and the plating film 111b.

### <Method for Manufacturing a Semiconductor Device of Embodiment 1>

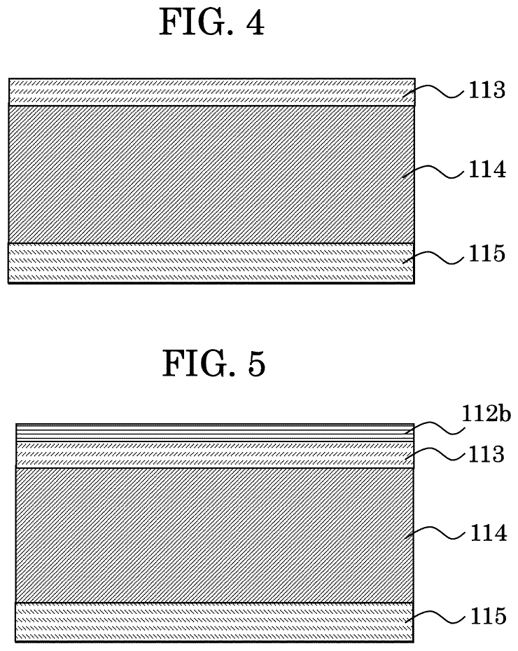

The method for manufacturing a semiconductor device according to Embodiment 1 will be described with reference to FIGS. 4 to 8. Note that the method for manufacturing the wiring connection part 102, which is a characteristic part of the semiconductor device 100 according to Embodiment 1, will be mainly described in detail.

FIG. 3 shows a cross-sectional view after each of the following processes: the formation of the first semiconductor layer 114 on the semiconductor substrate 115; the processing of the first semiconductor layer 114; and the formation of the insulating film 113 on the first semiconductor layer 114.

Before the formation of the first semiconductor layer 114, the formation of the first-conductivity-type second semiconductor layer 121, the semiconductor quantum well layer 122, and the second-conductivity-type third semiconductor layer 123, which constitute the ridge structure 101a of the light emitting part 101, and the processing of the stripe shape are completed.

Epitaxial crystal growth is one example of a method for forming each semiconductor layer. Metal Organic Chemical Vapor Deposition (MOCVD) is an example of the epitaxial crystal growth of semiconductor layers for semiconductor optical devices.

The insulating film 113 is generally made of a SiO₂ film. One example of the SiO₂ film deposition method is a CVD (Chemical Vapor Deposition) method. For example, a SiN film may be used instead of the SiO₂ film.

After deposition of the insulating film 113, the front surface electrode 112b is deposited on the insulating film 113, as shown in FIG. 5. The front surface electrode 112b may be deposited by, for example, a vacuum evaporation method or a sputtering method.

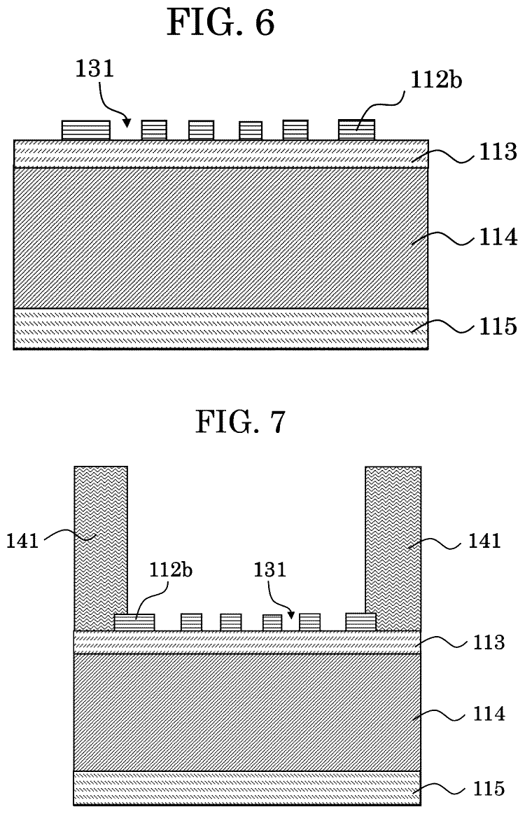

The front surface electrode 112b is processed to form the opening portions 131 in the front surface electrode 112b. One method for forming the opening portions 131 is, for example, to form a resist pattern corresponding to the opening portions 131 on the front surface electrode 112b by using photolithography and etching techniques, and then to etch the front surface electrode 112b until the front surface of the insulating film 113 is exposed. FIG. 6 is a cross-sectional view after the opening portions 131 are formed. Since the opening portions 131 are formed in the front surface electrode 112b at the same time with the original processing of the front surface electrode 112b, it is possible to manufacture the semiconductor device using the same manufacturing process as in the case where the method for manufacturing a semiconductor device according to Embodiment 1 is not provided. That is, the number of processes in the manufacturing method for a semiconductor device according to Embodiment 1 is the same as the number of processes in the manufacturing method for a conventional semiconductor device with a front surface electrode without opening portions.

FIG. 7 is a cross-sectional view of the wiring connection part 102 in which a resist mask 141 for forming the plating film 111b is formed. The resist mask 141 is formed through a process of forming a mask pattern with resist, that is, a process of resist application, pattern exposure, development, and the like.

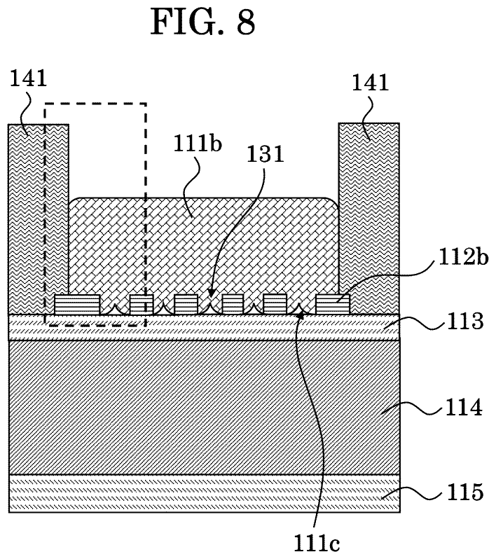

FIG. 8 is a cross-sectional view of the wiring connection part 102 after the plating film forming step. As described above, the part of the plating film 111b forms the portions 111c which extend toward the bottom side of the opening portions 131.

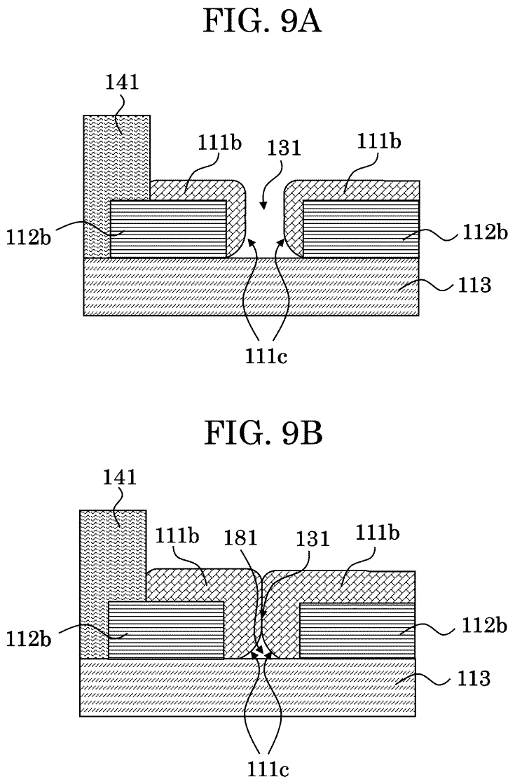

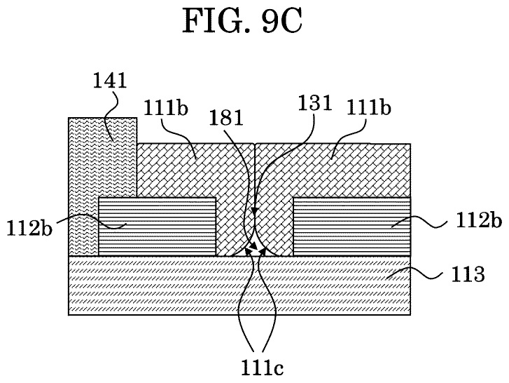

FIGS. 9A, 9B, and 9C are enlarged cross-sectional views of the region surrounded by the broken line in FIG. 8, and show the respective steps from the beginning of the plating film forming step to the processes shown in FIGS. 7 and 8 in order. A current is applied to the front surface electrode 112b to form the plating film 111b while a wafer having the resist pattern shown in FIG. 7 formed on the wafer is immersed in a plating solution. In this case, the plating film 111b is formed on a contact surface between the wafer and the plating solution.

FIG. 9A is a cross-sectional view showing an initial state of the plating film 111b in the plating film forming step. In the opening portions 131 in the front surface electrode 112b, the plating film 111b is formed along the side surface of the opening portion 131. In the deposition of plating film 111b, the thickness of the plating film formed on the side surface of the opening portions 131 in the front surface electrode 112b on the bottom side, that is, the side surface of the opening portions 131 on the insulating film 113 side, is thinner than the thickness of the plating film formed on the opening end side of the opening portions 131. This is because the plating material in the plating solution is consumed in the formation of the plating film on the side surfaces of the opening portions 131 in the front surface electrode 112b, and the supply of the plating solution to inside of the opening portions 131 is limited by the gradual narrowing of the opening portion width as the plating film 111b is formed on the side surfaces of the opening portions 131, resulting in a lower concentration of the plating solution at the bottom side of the opening portions 131 in the front surface electrode 112b.

When the formation of the plating film 111b further progresses from the state shown in FIG. 9A, the plating film formed on both side surfaces of the opening portions 131 are connected to each other on the upper side of the opening portions 131 in the front surface electrode 112b, as shown in FIG. 9B. That is, the opening portions 131 in the front surface electrode 112b is covered with the plating film 111b. As a result, voids 181 are formed between the insulating film 113 and the plating film 111b. After the plating film 111b formed on both side surfaces of the opening portions 131 are connected to each other, the plating solution is not newly supplied to the voids 181. As the formation of the plating film 111b further progresses, as shown in FIG. 9C, the plating film 111b increases in thickness upward, while leaving the voids 181.

The semiconductor device 100 according to Embodiment 1 has a device structure in which the contact area of the connecting electrode 104 with the signal input line is maintained and the contact area of the front surface electrode 112b and the insulating film 113 is reduced by forming the voids 181 through the manufacturing steps shown in FIGS. 4 to 8. The contact area can be further reduced by providing a plurality of opening portions 131 in the front surface electrode 112b, although the upper limit of the opening size of the opening portions 131 in the front surface electrode 112b is limited by the thickness of the plating film 111b in order for the void 181 to be formed.

### <Effects of Semiconductor Device of Embodiment 1>

As described above, according to the semiconductor device 100 of Embodiment 1, the electrostatic capacitance generated in the wiring connection part 102 can be reduced without deteriorating the connectivity between the signal input line and the connecting electrode 104 in the wiring connection part 102, thus providing an effect that a semiconductor device with improved high-frequency characteristics can be obtained.

### <Effects of Manufacturing Method for a Semiconductor Device of Embodiment 1>

According to the method for manufacturing a semiconductor device of Embodiment 1, the opening portions 131 in the front surface electrode 112b, which is a part of the connecting electrode 104, can be manufactured in the same manufacturing process as in the case where the method for manufacturing a semiconductor device of Embodiment 1 is not provided, thus providing an effect that a semiconductor device having excellent high-frequency characteristics can be manufactured without increasing the manufacturing cost.

### Embodiment 2

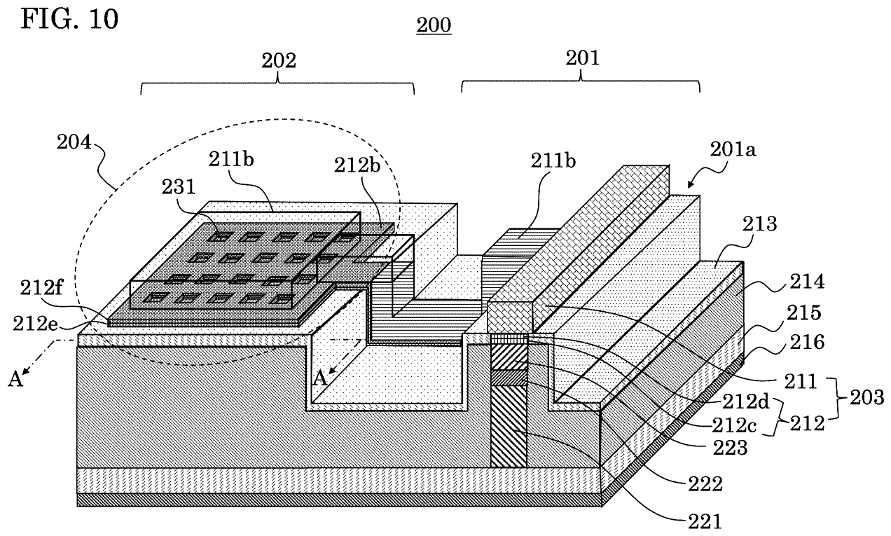

FIG. 10 is a schematic view of a semiconductor device 200 according to Embodiment 2. The semiconductor device 200 is a semiconductor optical device as an example, as in Embodiment 1. The components of the semiconductor device are basically the same as those of the semiconductor device 100 according to Embodiment 1. The semiconductor device 200 according to Embodiment 2 is different from the semiconductor device 100 according to Embodiment 1 in that a ridge-side front surface electrode 212 and a front surface electrode 212b are composed of two or more metal films, and that the opening area of opening portions 231 in the front surface electrode 212b is larger on the insulating film 113 side, that is, the bottom side, than on the opening end side.

FIG. 10 shows a structure of the ridge-side front surface electrode 212, which is composed of two layers of a first ridge-side front surface electrode 212c and a second ridge-side front surface electrode 212d from the insulating film 113 side. Note that, in FIG. 10, a plating film 211b is shown in a transparent manner in order to show the shape of the front surface electrode 212b of the connecting electrode 204.

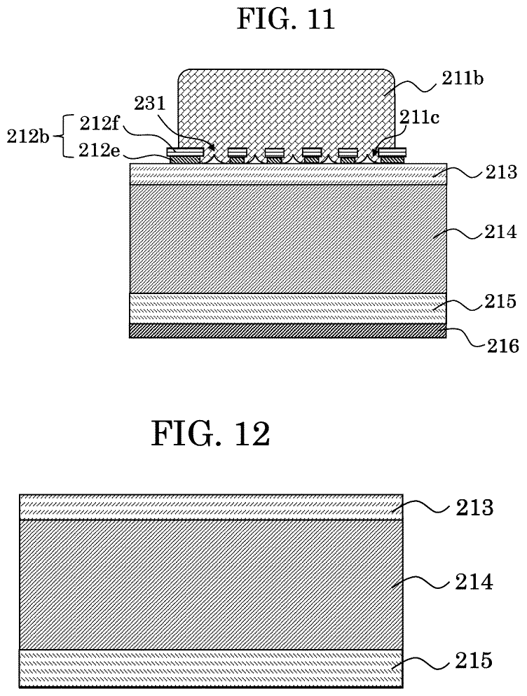

FIG. 11 is a cross-sectional view of a wiring connection part 202 taken along line A-A of FIG. 10. The cross-sectional view of the wiring connection part 202 of the semiconductor device 200 according to Embodiment 2 is different from that of the wiring connection part 102 of the semiconductor device 100 according to Embodiment 1 shown in FIG. 3 in that the front surface electrode 212b is composed of two layers, that are, a first front surface electrode 212e and a second front surface electrode 212f, in this order from the insulating film 113 side. In Embodiment 2, the case where the front surface electrode 212b is composed of two layers is given as an example, but the front surface electrode 212b may be composed of a multilayered structure with three or more layers.

The semiconductor optical device, which is an example of the semiconductor device 200 according to Embodiment 2, includes a light emitting part 201 and the wiring connection part 202. The light emitting part 201 includes: a ridge structure 201a formed on a semiconductor substrate 215; an insulating film 213 provided on both side surfaces of the ridge structure 201a; a ridge-side front surface electrode 212 provided in contact with the upper surface of the ridge structure 201a through an opening portion of the insulating film 213 formed on the upper surface of the ridge structure 201a; and a ridge-side plating film 211 provided on the ridge-side front surface electrode 212. Note that the ridge-side front surface electrode 212 and the ridge-side plating film 211 are collectively referred to as a ridge-side electrode 203.

The ridge structure 201a is composed of a first-conductivity-type second semiconductor layer 221, a semiconductor quantum well layer 222, and a second-conductivity-type third semiconductor layer 223, which are sequentially formed on the semiconductor substrate 215, and a first semiconductor layer 214 formed so as to cover the side surfaces of the respective layers. A back surface electrode 216 is provided on the back side of the semiconductor substrate 215, that is, on the side opposite to the front side on which the ridge structure 201a and the connecting electrode 204 are provided.

### <Method for Manufacturing a Semiconductor Device of Embodiment 2>

The method for manufacturing a semiconductor device according to Embodiment 2 will be described with reference to FIGS. 12 to 16. Note that the method for manufacturing the wiring connection part 202, which is a characteristic part of the semiconductor device 200 according to Embodiment 1, will be mainly described in detail.

FIG. 12 is a cross-sectional view after each of the following processes: the formation of the first semiconductor layer 214 on the semiconductor substrate 215; the processing of the first semiconductor layer 214; and the formation of the insulating film 213 on the first semiconductor layer 214.

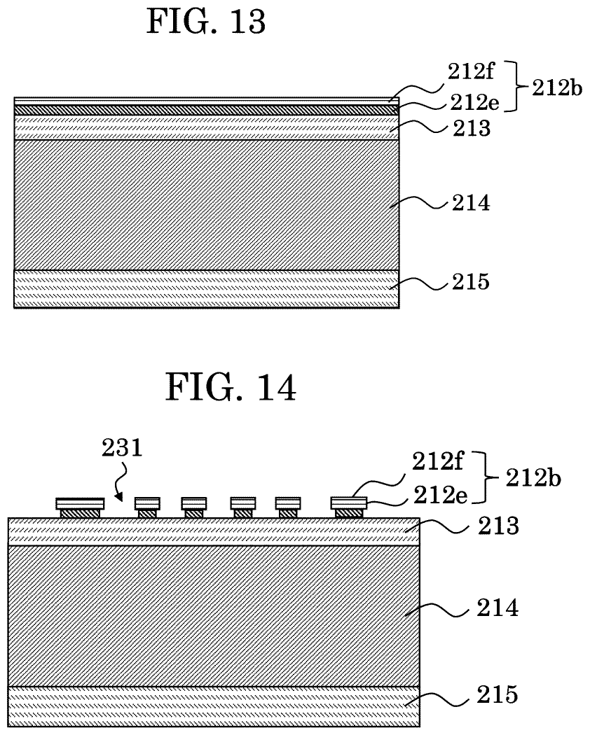

After the insulating film 213 is formed, as shown in FIG. 13, the front surface electrode 212b is formed on the insulating film 213. The front surface electrode 212b is composed of two layers, that are, the first front surface electrode 212e and the second front surface electrode 212f from the insulating film 213 side.

The front surface electrode 212b is processed to form the opening portions 231 in the front surface electrode 212b. As a method for forming the opening portions 231, for example, a resist pattern corresponding to the opening portions 231 is formed on the front surface electrode 212b by using the photolithography and the etching techniques, and then the front surface electrode 212b is etched until the front surface of the insulating film 213 is exposed, thereby forming the opening portions 231.

In the step of forming the front surface electrode 212b, each metal film of the front surface electrode 212b, which is composed of two layers, that are the first front surface electrode 212e and the second front surface electrode 212f, is selectively processed in order. For example, after forming opening portions by processing the second front surface electrode 212f using a chemical solution that selectively dissolves the second front surface electrode 212f, the first front surface electrode 212e is processed using a chemical solution that selectively dissolves the first front surface electrode 212e to form the opening portions 231 in which the bottoms thereof reach the insulating film 213. As shown in FIG. 14, the first front surface electrode 212e is processed such that the opening width of the opening portions 231 on the first front surface electrode 212e side is larger than that on the second front surface electrode 212f side. That is, the shape of the opening portion 231 is such that the opening area at the bottom of the opening portion 231 on the insulating film 213 side is larger than the opening area at the opening end of the opening portion 231 on the plating film 211b side.

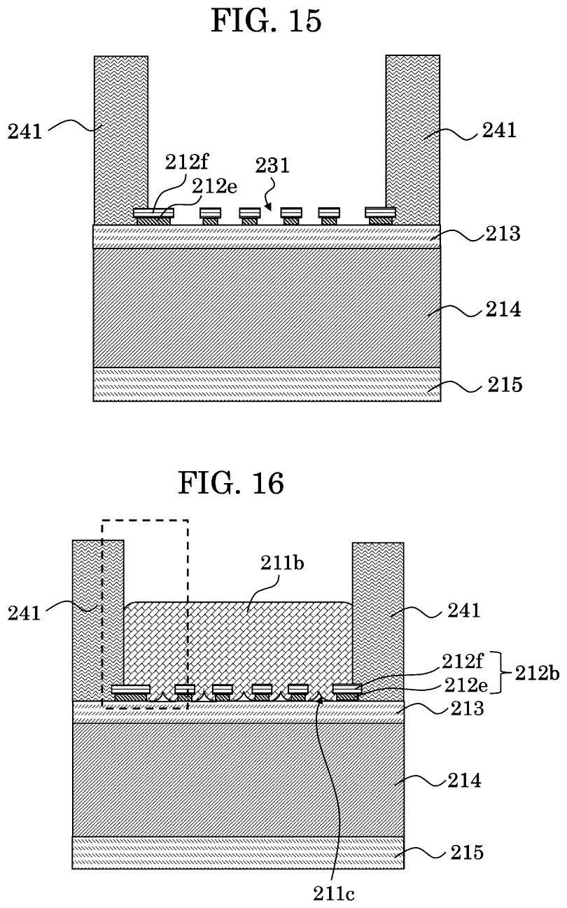

FIG. 15 is a cross-sectional view of the wiring connection part 202 after a resist mask 241 for forming the plating film 211b shown in FIGS. 10 and 11 is formed. The resist mask 241 is formed through a process of forming a mask pattern with resist, that is, a process of resist application, pattern exposure, development, and the like.

FIG. 16 is a cross-sectional view of the wiring connection part 202 after the plating film forming step. The part of the plating film 211b forms the portions 211c which extend toward the bottom side of the opening portions 231.

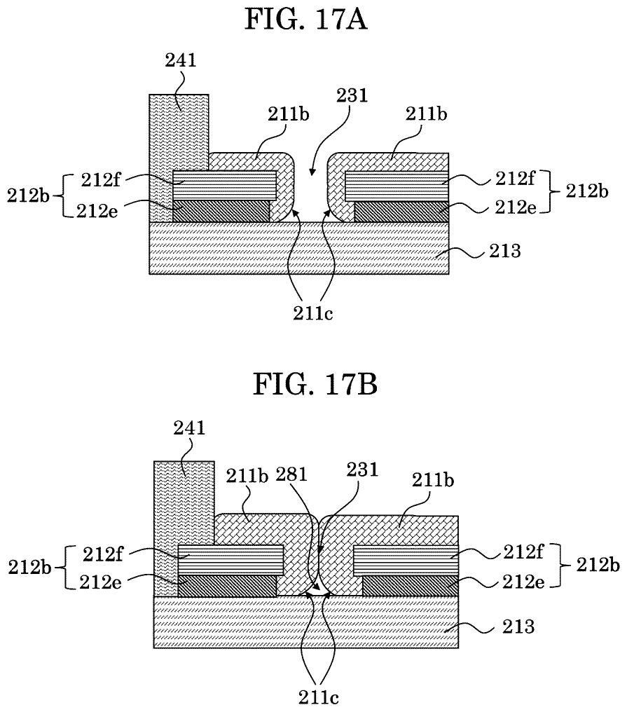

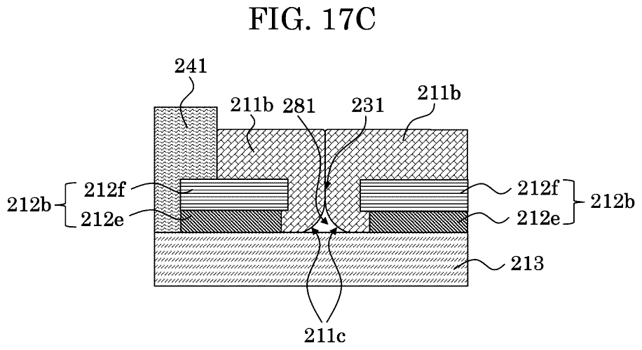

FIGS. 17A, 17B, and 17C are enlarged cross-sectional views of the region surrounded by the broken line in FIG. 16, and show the respective steps from the beginning of the plating film forming process to the processes shown in FIGS. 15 and 16 in order. A current is applied to the front surface electrode 212b to form the plating film 211b while a wafer having the resist pattern shown in FIG. 15 is immersed in a plating solution. In this case, the plating film 211b is formed on the contact surface between the wafer and the plating solution.

FIG. 17A is a cross-sectional view showing an initial state of the plating film 211b in the plating film forming step. The plating film 211b is formed in the opening portions 231 in the front surface electrode 212b along the stepped side surfaces of the opening portions 131 generated between the first front surface electrode 212e and the second front surface electrode 212f.

As the formation of the plating film 211b progresses further from the state shown in FIG. 17A, the plating film 211b formed on both side surfaces of each opening portion 231 are connected to each other in the upper portion of the opening portion 231 in the front surface electrode 212b as shown in FIG. 17B. That is, the opening portions 231 in the front surface electrode 212b are covered with the plating film 211b. As a result, voids 281 are formed between the insulating film 213 and the plating film 211b. As the formation of the plating film 211b further progresses, the plating film 211b increases in thickness upward, while leaving the voids 281 as shown in FIG. 17C.

In the semiconductor device 200 according to Embodiment 2, the opening portions 231 in the front surface electrode 212b have a wide opening width (a wide opening area) on the bottom side, and thus the voids 281 formed in the stage shown in FIG. 17B has a larger volume than the volume of the voids 181 of the semiconductor device 100 according to Embodiment 1 shown in FIGS. 9B and 9C, and the opening area on the bottom side of the opening portions 231 can be formed larger. Therefore, the semiconductor device 200 according to Embodiment 2 can further reduce the electrostatic capacitance generated in the wiring connection part as compared with the semiconductor device 100 according to Embodiment 1, thus providing an effect of improving the high-frequency characteristics of a semiconductor device.

### <Effects of Semiconductor Device of Embodiment 2>

As described above, in the semiconductor device 200 according to Embodiment 2, the front surface electrode 212b constituting the connecting electrode 204 is composed of two layers, that are, the first front surface electrode 212e and the second front surface electrode 212f, and the opening area of the opening portion 231 on the insulating film 213 side is larger than the opening area thereof on the plating film 211b side. Therefore, the electrostatic capacitance generated at the wiring connection part can be further reduced, thus providing an effect that a semiconductor device with improved high-frequency characteristics can be obtained.

### <Effects of Method for Manufacturing a Semiconductor Device of Embodiment 2>

In the method for manufacturing a semiconductor device according to Embodiment 2, the front surface electrode 212b constituting the connecting electrode 204 is composed of two layers, that are, the first front surface electrode 212e and the second front surface electrode 212f, and the opening portions 231 are processed to have a shape in which the opening area of the opening portions 231 on the insulating film 213 side is larger than the opening area thereof on the plating film 211b side. Therefore, the electrostatic capacitance generated at the wiring connection part can be further reduced, thus providing an effect that a semiconductor device with improved high-frequency characteristics can be easily manufactured.

### Embodiment 3

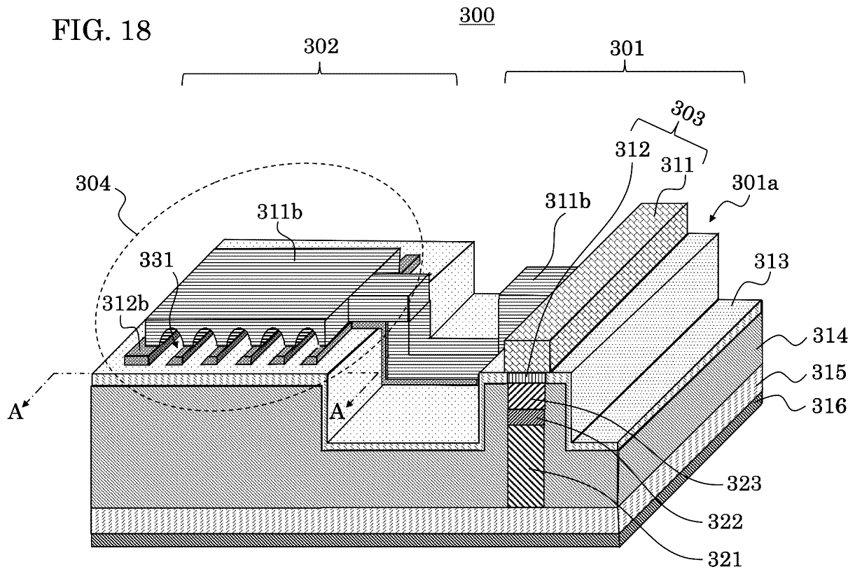

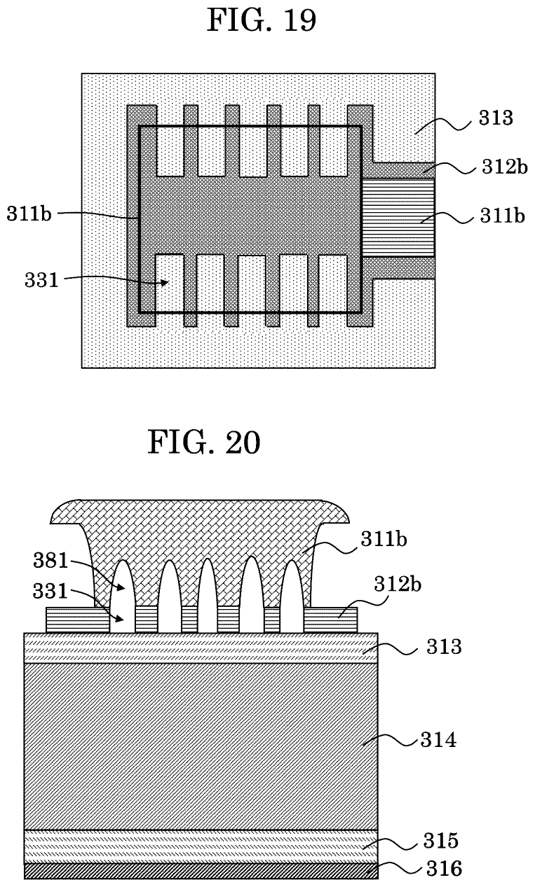

FIG. 18 is a schematic view of a semiconductor device 300 according to Embodiment 3. FIG. 19 is a top view of the wiring connection part 302 of the semiconductor device 300 according to Embodiment 3.

The semiconductor device 300 is a semiconductor optical device as an example, as in Embodiment 1 and Embodiment 2. The components of the semiconductor device 300 are basically the same as those of the semiconductor device 100 according to Embodiment 1. The semiconductor device 300 according to Embodiment 3 is different from the semiconductor device 100 according to Embodiment 1 in that, in the semiconductor device 300 according to Embodiment 3, a front surface electrode 312b constituting a connecting electrode 304 has a notch-shape (hereinafter referred to as notch-shaped opening portions) in which the opening portions extend from the outer edge portion toward the inner side of the front surface electrode 312b in the part of the front surface electrode 312b having a rectangular shape in a top view, as shown in FIG. 19.

A plating film 311b is formed so as to cover notch-shaped opening portions 331 in the front surface electrode 312b. Each notch-shaped opening portion 331 in the front surface electrode 312b has a void 381 between an insulating film 313 and the plating film 311b. The void 381 has the feature of being open to the outside from the notch-shaped opening portions 331 in the outer edge of the front surface electrode 312b.

FIG. 20 is a cross-sectional view of the wiring connection part 302 taken along line A-A shown in FIG. 18. The wiring connection part 302 includes: a first semiconductor layer 314 formed on a semiconductor substrate 315; the insulating film 313 provided on the first semiconductor layer 314; and the connecting electrode 304 composed of the front surface electrode 312b and the plating film 311b formed on the insulating film 313. A back surface electrode 316 is provided on the back surface side of the semiconductor substrate 315.

The front surface electrode 312b is provided with a plurality of notch-shaped opening portions 331 at regular intervals as shown in FIG. 19. The plurality of notch-shaped opening portions 331 may be provided at equal intervals from each other. In the cross-sectional view of the wiring connection part 302 shown in FIG. 20, the notch-shaped opening portions 331 are arranged at regular intervals. The insulating film 313 is exposed on the bottom surface of the notch-shaped opening portions 331.

The plating film 311b is formed on the front surface electrode 312b. The plating film 311b is provided with recess portions toward the inside of the plating film 311b so as to face the openings generated by the notch-shaped opening portions 331 in the front surface electrode 312b. The space formed by the notch-shaped opening portions 331 on the front surface electrode 312b side and the recess portions formed toward the inside of the plating film 311b are integrated to form the voids 381.

The semiconductor optical device, which is an example of the semiconductor device 300 according to Embodiment 3, includes a light emitting part 301 and the wiring connection part 302. The light emitting part 301 includes: a ridge structure 301a formed on the semiconductor substrate 315; the insulating film 313 provided on both side surfaces of the ridge structure 301a; a ridge-side front surface electrode 312 provided in contact with the upper surface of the ridge structure 301a through the opening portion of the insulating film 313 formed on the upper surface of the ridge structure 301a; and a ridge-side plating film 311 provided on the ridge-side front surface electrode 312. Note that the ridge-side front surface electrode 312 and the ridge-side plating film 311 are collectively referred to as a ridge-side electrode 303.

The ridge structure 301a is composed of: a first-conductivity-type second semiconductor layer 321; a semiconductor quantum well layer 322; and a second-conductivity-type third semiconductor layer 323; which are sequentially formed on the semiconductor substrate 315, and a first semiconductor layer 314 formed so as to cover the side surfaces of the respective layers. A back surface electrode 316 is provided on the back side of the semiconductor substrate 315, that is, on the side opposite to the front side on which the ridge structure 301a and the connecting electrode 304 are provided.

### <Method for Manufacturing a Semiconductor Device of Embodiment 3>

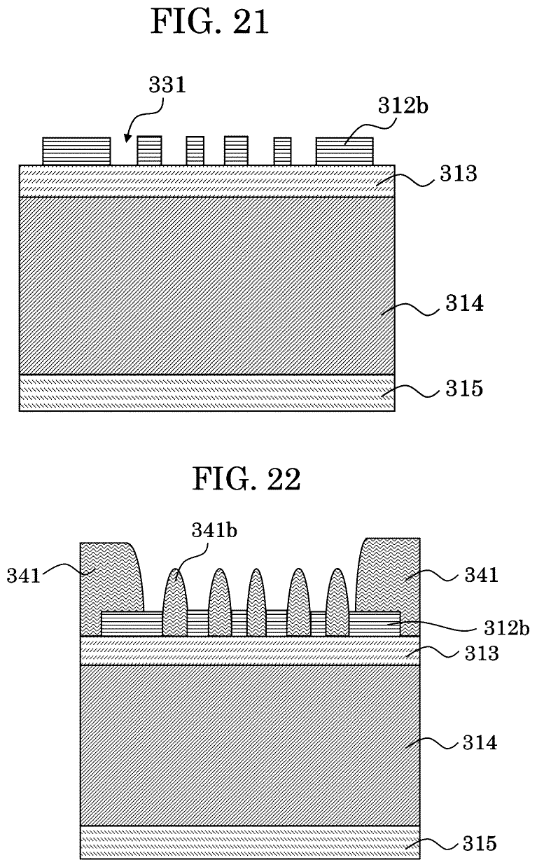

A method for manufacturing the wiring connection part 302, which is a characteristic part of the method for manufacturing the semiconductor device 300 according to Embodiment 3, will be described with reference to FIGS. 21 to 23.

The front surface electrode 312b is processed to form the notch-shaped opening portions 331 in the front surface electrode 312b. As a method for forming the notch-shaped opening portions 331, for example, a resist pattern corresponding to the notch-shaped opening portions 331 is formed on the front surface electrode 312b by using the photolithography and the etching techniques, and then the front surface electrode 312b is etched until the front surface of the insulating film 313 is exposed, thereby forming the notch-shaped opening portions 331. FIG. 21 is a cross-sectional view after the notch-shaped opening portions 331 are formed.

FIG. 22 is a cross-sectional view of the wiring connection part 302 in which a resist mask 341 for forming the plating film 311b is formed. The resist mask 341 is formed through a process of forming a mask pattern with resist, that is, a process of resist application, pattern exposure, development, and the like.

The difference between the resist mask shown in FIG. 7 of Embodiment 1 or FIG. 15 of Embodiment 2 and the resist mask of Embodiment 3 is that in Embodiment 3, the resist mask 341b is also formed in the notch-shaped opening portions 331 in the front surface electrode 312b, as shown in FIG. 22. Note that a thickness of the resist mask 341b is thinner than that of the resist mask 341 at the outer edge of the front surface electrode 312b.

The shape of the resist mask as shown in FIG. 22 can be achieved by setting the exposure condition for the size of the notch-shaped opening portions 331 in the front surface electrode 312b to be slightly overexposed in the resist mask forming step, and forming the resist mask 341 and the resist mask 341b at the same time. Since the resist mask 341 and the resist mask 341b are connected to each other through the notch-shaped opening portions 331 in the front surface electrode 312b, the thicknesses of the resist mask 341 and the resist mask 341b continuously change.

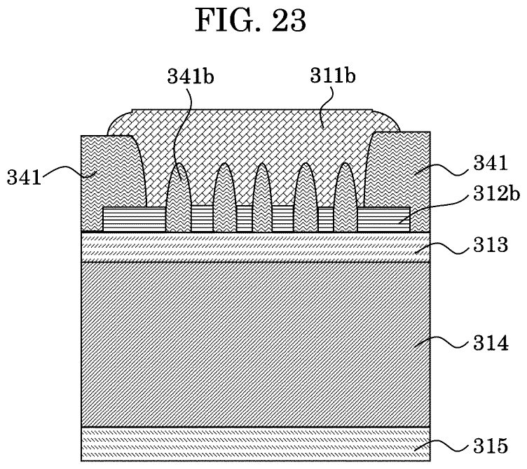

FIG. 23 is a cross-sectional view of the wiring connection part 302 after the plating film forming step. The plating film 311b is formed so as to cover the resist mask 341b formed in the notch-shaped opening portions 331 in the front surface electrode 312b.

After the plating film 311b is formed, the resist mask is removed, resulting in the cross-sectional shape of the wiring connection part 302 as shown in FIG. 20. The resist mask 341b formed in the notch-shaped opening portions 331 in the front surface electrode 312b is connected to the resist mask 341 formed in the outer edge portion of the front surface electrode 312b, therefore, the resist mask 341b is removed at the same time in the resist removal step. As a result, the voids 381 are formed between the insulating film 313 and the plating film 311b within the notch-shaped opening portions 331 in the front surface electrode 312b.

The semiconductor device 300 according to Embodiment 3 is characterized in that the volume of the voids 381 are larger than the voids of the semiconductor device 100 according to Embodiment 1 and the voids of the semiconductor device 200 according to Embodiment 2. Therefore, in the semiconductor device 300 according to Embodiment 3, the electrostatic capacitance generated in the wiring connection part 302 is further reduced, thus providing an effect of improving the high-frequency characteristics of a semiconductor device.

### <Effects of Semiconductor Device of Embodiment 3>

As described above, the semiconductor device 300 according to Embodiment 3 has a structure in which the notch-shaped opening portions 331 are provided in the front surface electrode 312b and the large-volume voids are provided, enabling further reduction of the electrostatic capacitance generated at the wiring connection part, thus providing an effect that a semiconductor device with improved high-frequency characteristics can be obtained.

### <Effects of Method for Manufacturing a Semiconductor Device of Embodiment 3>

In the method for manufacturing a semiconductor device according to Embodiment 3, the exposure conditions for the size of the notch-shaped opening portions 331 in the front surface electrode 312b are set to be slightly overexposed in the resist mask forming step, and the resist mask 341 and the resist mask 341b are formed at the same time. Therefore, it is possible to easily form the voids with a large volume, thus providing an effect of easily manufacturing semiconductor devices with further improved high-frequency characteristics.

### Embodiment 4

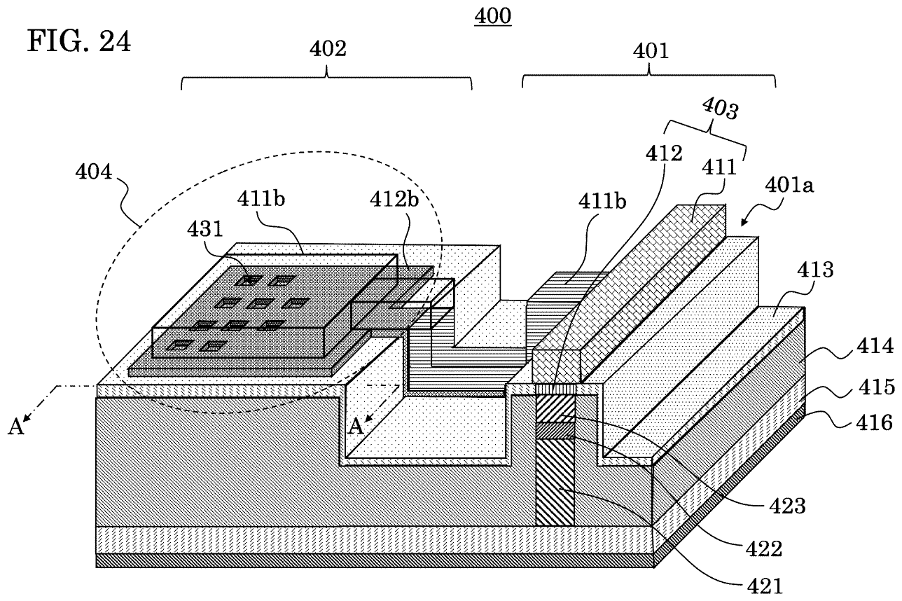

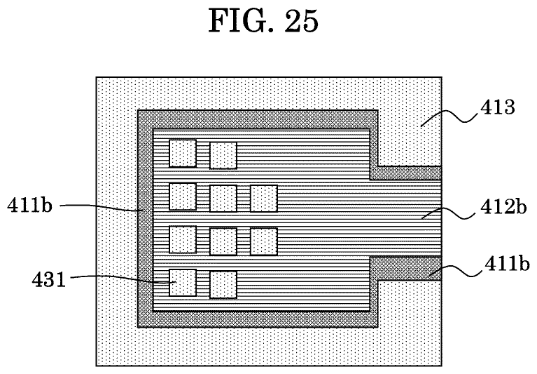

FIG. 24 is a schematic view of a semiconductor device 400 according to Embodiment 4. FIG. 25 is a view of a wiring connection part 402 of the semiconductor device 400 according to Embodiment 4 from the upper surface of the semiconductor device 400. Note that, in FIGS. 24 and 25, a plating film 411b is shown in a transparent manner in order to show a shape of a front surface electrode 412b of a connecting electrode 404. The semiconductor device 400 is a semiconductor optical device as an example, as in Embodiment 1. The components of the semiconductor device 400 are basically the same as those of the semiconductor device 100 according to Embodiment 1.

The semiconductor device 400 according to Embodiment 4 is different from the semiconductor device 100 according to Embodiment 1 in that the opening portions 131 are arranged in the lattice pattern over the entire rectangular-shaped portion of the front surface electrode 112b in the semiconductor device 100, whereas opening portions 431 are arranged in the lattice pattern in a partial region of the rectangular-shaped portion of the front surface electrode 412b in the semiconductor device 400.

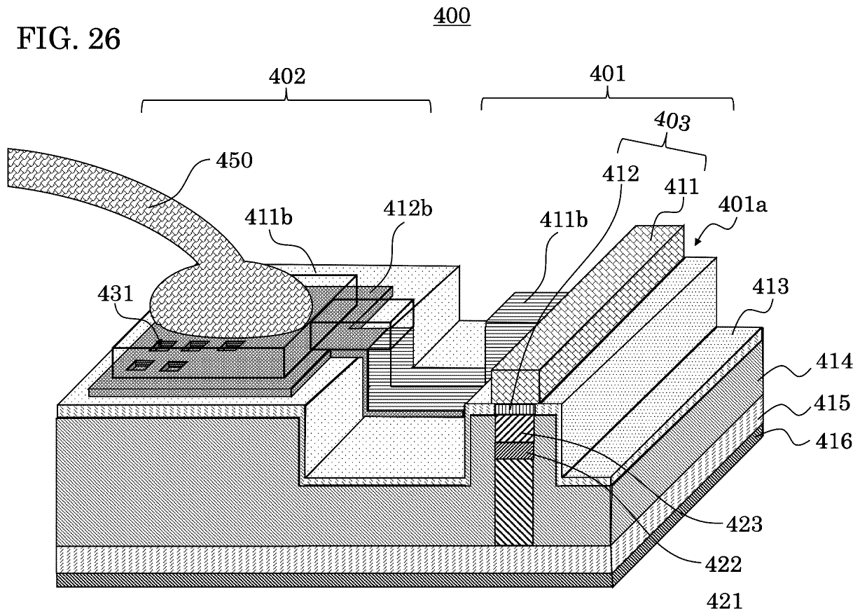

FIG. 26 is a schematic view of a semiconductor device 400 with a gold wire 450, which is an input signal line, connected to the connecting electrode 404. In FIG. 26, the plating film 411b is shown in a transparent manner in order to show a shape of the front surface electrode 412b of the connecting electrode 404.

The semiconductor optical device, which is an example of the semiconductor device 400 according to Embodiment 4, includes a light emitting part 401 and the wiring connection part 402. The light emitting part 401 includes: a ridge structure 401a formed on a semiconductor substrate 415; an insulating film 413 provided on both side surfaces of the ridge structure 401a; a ridge-side front surface electrode 412 provided in contact with the upper surface of the ridge structure 401a through an opening portion of the insulating film 413 formed on the upper surface of the ridge structure 401a; and a ridge-side plating film 411 provided on the ridge-side front surface electrode 412. Note that the ridge-side front surface electrode 412 and the ridge-side plating film 411 are collectively referred to as a ridge-side electrode 403.

The ridge structure 401a is composed of a first-conductivity-type second semiconductor layer 421, a semiconductor quantum well layer 422, and a second-conductivity-type third semiconductor layer 423, which are sequentially formed on the semiconductor substrate 415, and a first semiconductor layer 414 formed so as to cover the side surfaces of the respective layers. A back surface electrode 416 is provided on the back side of the semiconductor substrate 415, that is, on the side opposite to the front side on which the ridge structure 401a and the connecting electrode 404 are provided.

As described above, the semiconductor device 400 according to Embodiment 4 is characterized in that the opening portions 431 in the front surface electrode 412b are partially arranged. The connection of the gold wire 450 to the connecting electrode 404 causes the front surface electrode 412b to be pulled in the direction of the gold wire 450, that is, to be subjected to tensile stress. Therefore, in the semiconductor device 400 according to Embodiment 4, the opening portions 431 should not be arranged at a part of the front surface electrode 412b where the tensile stress from the gold wire 450 would be strong. Such arrangement of the opening portions 431 allows the connection between the gold wire 450 and the connecting electrode 404 to be stably maintained even when the tensile stress is subjected from the gold wire 450, thus providing an effect of improving the reliability of the semiconductor device 400.

### <Effects of Semiconductor Device of Embodiment 4>

As described above, according to the semiconductor device 400 of Embodiment 4, since the opening portions 431 are arranged in a lattice pattern in the part of the rectangular-shaped portion of the front surface electrode 412b, the connection between the gold wire 450 and the connecting electrode 404 can be stably maintained, thus providing an effect that a semiconductor device having excellent high-frequency characteristics and high reliability can be obtained.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

100, 200, 300, 400 semiconductor device
101, 201, 301, 401 light emitting part
101a, 201a, 301a, 401a ridge structure
102, 202, 302, 402 wiring connection part
103, 203, 303, 403 ridge-side electrode
104, 204, 304, 404 connecting electrode
111, 211, 311, 411 ridge-side plating film
111b, 211b, 311b, 411b plating film
111c, 211c portion
112, 212, 312, 412 ridge-side front surface electrode
112b, 212b, 312b, 412b front surface electrode
113, 213, 313, 413 insulating film
115, 215, 315, 415 semiconductor substrate
116, 216, 316, 416 back surface electrode
121, 221, 321, 421 first-conductivity-type second semiconductor layer
122, 222, 322, 422 semiconductor quantum well layer
123, 223, 323, 423 second-conductivity-type third semiconductor layer
131, 231, 431 opening portion
141, 241, 341, 341b resist mask
181, 281, 381 void
212c first ridge-side front surface electrode
212d second ridge-side front surface electrode
212e first front surface electrode
212f second front surface electrode
331 notch-shaped opening portion
450 gold wire

1. A semiconductor device comprising:
a semiconductor substrate;
a first semiconductor layer formed on the semiconductor substrate;
an insulating film formed on the first semiconductor layer; and
a connecting electrode including a front surface electrode formed in contact with the insulating film and having a plurality of opening portions that expose the insulating film on the bottom surface, and a plating film formed in contact with the front surface electrode and covering the opening portions, the plating film having one portion that extends along one side surface of each opening portion toward the bottom side of the opening portion and has a tip that contacts the insulating film on the bottom surface of the opening portion, the plating film having the other portion that extends along the other side surface opposite the one side surface of the opening portion and has a tip that contacts the insulating film on the bottom surface of the opening portion, the insulating film being exposed on the bottom surface in a void formed in the opening portion by a mutual contact between the one portion and the other portion in the opening portion width direction.

2.-3. (canceled)

4. The semiconductor device according to claim 1, wherein
the front surface electrode has a rectangular-shaped portion in a top view, and the opening portions are arranged in a lattice pattern in the rectangular-shaped portion of the front surface electrode.

5. The semiconductor device according to claim 4, wherein
the opening portions are arranged in a lattice pattern over the entire rectangular-shaped portion of the front surface electrode.

6. The semiconductor device according to claim 4, wherein
the opening portions are arranged in the lattice pattern in a part of the rectangular-shaped portion of the front surface electrode.

7. The semiconductor device according to claim 4, wherein
the plurality of opening portions are arranged at regular intervals.

8. The semiconductor device according to claim 1, wherein
the front surface electrode is composed of two layers of a first front surface electrode on the insulating film side and a second front surface electrode formed on the first front surface electrode, and an opening area of the opening portions on the insulating film side is larger than an opening area of the opening portions on the plating film side.

9. A semiconductor device comprising:
a semiconductor substrate;
a first semiconductor layer formed on the semiconductor substrate;
an insulating film formed on the first semiconductor layer;
a connecting electrode including a front surface electrode formed in contact with the insulating film and having a plurality of opening portions that expose the insulating film on the bottom surface, and a plating film formed in contact with the front surface electrode and having recessed portions on the side of the front surface electrode, the recessed portions being opposed to the opening portions.

10. The semiconductor device according to claim 4, wherein
the front surface electrode has a rectangular-shaped portion in a top view, and the plurality of opening portions have a notch-shape extending from the outer edge of the rectangular-shaped portion of the front surface electrode toward the interior side.

11. The semiconductor device according to claim 9, wherein
the plurality of notch-shaped opening portions are arranged at regular intervals.

12. The semiconductor device according to claim 9, wherein
a light emitting part is provided on the semiconductor substrate and has a ridge structure including a first-conductivity-type second semiconductor layer, a semiconductor quantum well layer, and a second-conductivity-type third semiconductor layer, and
the second-conductivity-type third semiconductor layer and the connecting electrode are electrically connected to each other.

13. A method for manufacturing a semiconductor device, comprising:
a crystal growth step of growing a first semiconductor layer on a semiconductor substrate;
an insulating film forming step of forming an insulating film on the first semiconductor layer;
a front surface electrode forming step of forming a front surface electrode, on the insulating film, having a plurality of opening portions that expose the insulating film on the bottom surface; and
a plating film forming step of depositing a plating film so as to cover the opening portions on the front surface electrode, the plating film having one portion that extends along one side surface of each opening portion toward the bottom side of the opening portion and has a tip that contacts the insulating film on the bottom surface of the opening portion, the plating film having the other portion that extends along the other side surface opposite the one side surface of the opening portion and has a tip that contacts the insulating film on the bottom surface of the opening portion, the insulating film being exposed on the bottom surface in a void formed in the opening portion by a mutual contact between the one portion and the other portion in the opening portion width direction.

14. (canceled)

15. The method for manufacturing a semiconductor device according to claim 13, wherein
in the front surface electrode forming step, two layers composed of a first front surface electrode on the insulating film side and a second front surface electrode on the first front surface electrode are deposited as the front surface electrode, and
the second front surface electrode is processed using a chemical solution that selectively dissolves the second front surface electrode, and then the first front surface electrode is processed using a chemical solution that selectively dissolves the first front surface electrode.

16. A method for manufacturing a semiconductor device comprising:
a crystal growth step of growing a first semiconductor layer on a semiconductor substrate;
an insulating film forming step of depositing an insulating film on the first semiconductor layer;
a front surface electrode forming step of forming a front surface electrode, on the insulating film, having a plurality of opening portions that expose the insulating film on the bottom surface; and
a plating film forming step of forming a plating film on the front surface electrode, the plating film having recessed portions opposed to the opening portions on the side in contact with the front surface electrode.

17. The semiconductor device according to claim 1, wherein
a light emitting part is provided on the semiconductor substrate and has a ridge structure including a first-conductivity-type second semiconductor layer, a semiconductor quantum well layer, and a second-conductivity-type third semiconductor layer; and
the second-conductivity-type third semiconductor layer and the connecting electrode are electrically connected to each other.
